(19) United States
(12) Patent Application Publication
(10) Pub. No.: US 2008/0124935 A1
(43) Pub. Date: May 29, 2008

(54) Two-step process for manufacturing deep trench

(75) Inventors: Hong-Long Chang, Hsinchu City (TW); Yi-Hsiung Lin, Zhonghe City (TW); Chris Shyu, Taipei City (TW)

Correspondence Address: NIXON PEABODY LLP - PATENT GROUP, 1100 CLINTON SQUARE, ROCHESTER, NY, 14604, US

(73) Assignee: Promos Technologies Inc., Hsinchu (TW)

(21) Appl. No.: 11/641,573

(22) Filed: Dec. 19, 2006

(30) Foreign Application Priority Data
Sep. 15, 2006 (TW) 0951349290

(51) Int. Cl. H01L 21/71

(52) U.S. Cl. 438/700; 257/E21.536

(57) ABSTRACT

A two-step process for manufacturing a deep trench in a semiconductor device that prevents shorts and leakages between neighboring capacitors due to over etching is disclosed. The process comprises conducting a first etching step to remove a portion of a substrate to form a trench with a first determined depth therein; conducting a thermal oxidation to form an oxide film on the sidewall of the trench; and conducting a second etching step to remove a portion of the substrate under the trench to form a deep trench with a second determined depth.

This application claims priority to Taiwan Patent Application No. 095134290 filed on Sep. 15, 2006.

### CROSS-REFERENCES TO RELATED APPLICATIONS

Not applicable.

### BACKGROUND OF THE INVENTION

1. Field of the Invention

The subject invention relates to a process for manufacturing a deep trench in a semiconductor device, especially relates to a two-step process for manufacturing a deep trench.

2. Descriptions of the Related Art

As semiconductor devices are developed according to deep submicron and nanometer process technology, the specification requirements of miniaturization and high integration level are in increasing demand. In the case of a dynamic random access memory (“DRAM”) device, the structure thereof must meet the requirement of miniaturizing in size while still maintaining increased memory capacity. Therefore, the previous designs and manufacturing methods for capacitors in DRAM should be changed to meet the current trend of development without problems due to shorts and/or leakages between capacitors.

Based on the structure of the capacitor contained, DRAM typically can be classified into two types: one utilizes stack capacitors and the other utilizes deep trench capacitors. Because of the aforementioned trends in the developments of DRAM, no matter the type, there are more and more difficulties encountered in the manufacturing process and problems needed to be solved.

Taking the advanced trench DRAM manufacturing process as an example, the depth of the deep trench is usually deeper than 5 nanometers. For storage nodes, the trench depth exceeds 7 nanometers, despite further miniaturizations in the design of DRAM cells. Even 7 to 8 nanometers should be maintained in order to provide a substantial trench surface area for capacitor storage. In conventional trench manufacturing processes, since a considerable amount of etching time is required to form a trench, the sidewall of the trench needs to be protected from over etching during this process. A method of adjusting the reaction gases for dry etching is usually adopted so that a thin film, called a polymer layer, is generated on the sidewall of the trench during the etching process to protect the sidewall from an unexpected over etching. Thus, the yield for the process can be increased.

Although the sidewall of a trench can be protected from being over etched via a polymer layer, a complete polymer protection layer normally doe not form on the corner of the trench sidewall, resulting in insufficient corner protection. Therefore, over etching easily occurs on the sidewall of the trench to leave striation thereon, as shown in FIG. 1.

FIG. 1 is a local micrograph (128×128) of the front view of a deep trench. The deep trench was provided with the protection of a polymer layer formed during the etching process using a reaction gas selected from a group consisting of HeO₂, SiF₄, NF₃, HBr, O₂, and combinations thereof, under pressure at 100 to 500 mini torr. FIG. 1 also shows an irregular contour on the corners of the deep trench capacitor structure. In general, the irregular contour is generated on the sidewall of the trench if the trench depth is over 3 nanometers. Striations occurred on the sidewall will lead to problems such as shorts and leakages between neighboring capacitors, accordingly decreasing the yield. Consequently, it is desired to improve the conventional processes for manufacturing deep trench capacitor structures to meet the requirements of miniaturization and high integration level of DRAM devices.

### SUMMARY OF THE INVENTION

One objective of the subject invention is to provide a process for manufacturing a deep trench while eliminating the problems of shorts and leakages between neighboring capacitors as a result of over etching.

The subject invention provides a deep trench structure via a two-step process. In the two-step process, after the formation of a trench with a first predetermined depth at a first etching step and the cleaning of the sidewall of the trench, an oxide film is formed on the sidewall of the trench via a thermal oxidation. Thereafter, a second etching step is conducted to further etch the trench to a second predetermined depth to form a deep trench with a desired depth.

The detailed technology and preferred embodiments implemented for the subject invention are described in the following paragraphs accompanying the appended figures for people skilled in this field to well appreciate the features of the claimed invention.

### BRIEF DESCRIPTION OF THE DRAWINGS

FIG. 1 depicts a local micrograph of the front view of a conventional deep trench capacitor with an irregular contour; and

FIGS. 2 to 7 depict schematic views of a two-step process of the subject invention for manufacturing a deep trench.

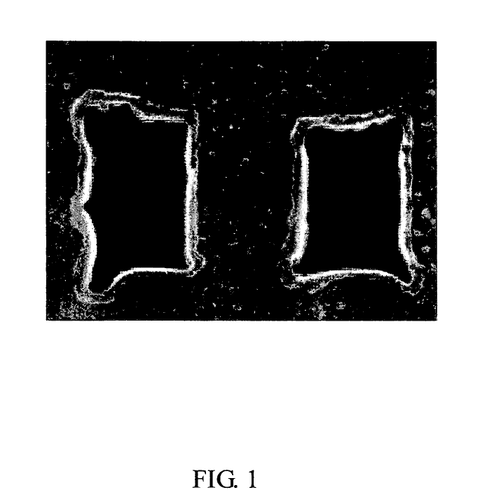

### DESCRIPTION OF THE PREFERRED EMBODIMENT

The following disclosure depicts to the two-step process of the subject invention for manufacturing a deep trench structure in a DRAM device while eliminating problems due to over etching present in conventional manufacturing processes. The subject invention is adapted to any manufacturing processes of trench capacitors. For the reason of easily understanding the features of the subject invention, a specific embodiment will be disclosed to show the application of the subject invention.

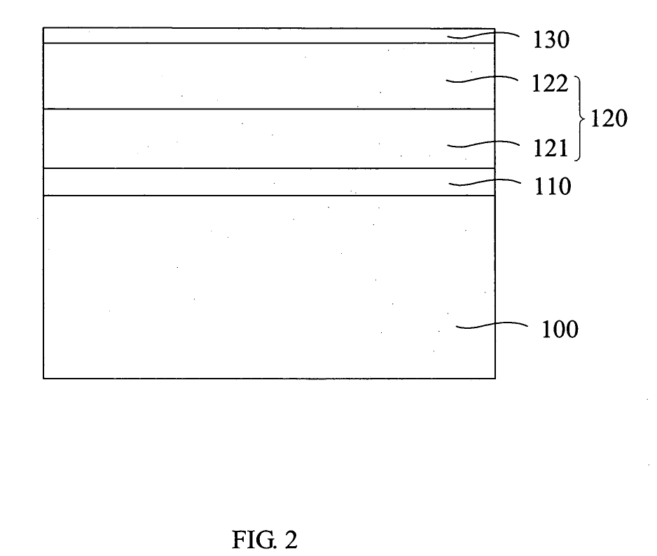

First, referring to FIG. 2, a pad layer 110, a sacrificial layer 120, and a mask layer 130 are formed sequentially on a silicon substrate 100. In a real application, the pad layer 110 may be a silicon nitride layer, the sacrificial layer 120 may be a silicon-oxide layer, and the mask layer 130 may be a polysilicon layer. Preferably, the silicon oxide layer is a composite layer comprising, for example, but not limited to, a BSG (Borosilicate Glass) layer 121 and a USG (Undoped Silicate Glass) layer 122.

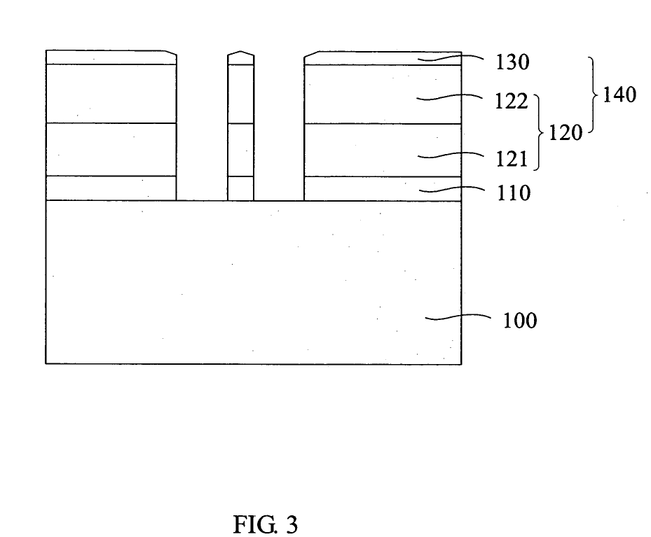

Next, a proper mask (not shown) is adopted to conduct a photolithograph process to transfer the pattern of the mask to the mask layer 130 on the silicon substrate 100. Then, the patterned mask layer 130 is used as a mask to transfer its pattern to the sacrificial layer 120 and the pad layer 110. The patterned mask layer 130 in combination with the patterned sacrificial layer 120 to provide a patterned composite layer 140 serving as a mask for the manufacture of a deep trench, as shown in FIG. 3.

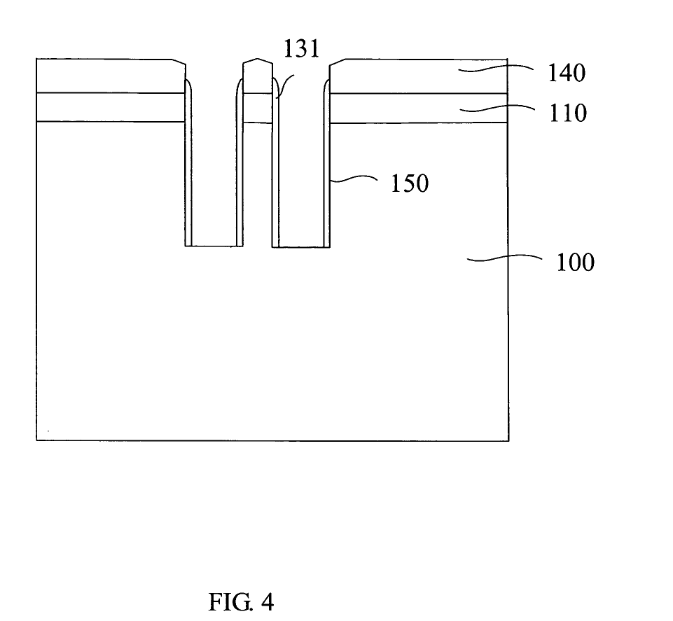

Thereafter, a first etching step for manufacturing a deep trench is outlined below. Referring to FIG. 4, the patterned composite layer 140 is used as an etching mask to remove a portion of the substrate 100 exposed outside the etching mask. For example, but not limited to, an anisotropic etching process can be conducted for such removal by using a reaction gas selected from a group consisting of HeO₂, SiF₄, NF₃, HBr, O₂, and combinations thereof. The first etching step is stop as a trench 150 with a first predetermined depth is formed in the substrate 100.

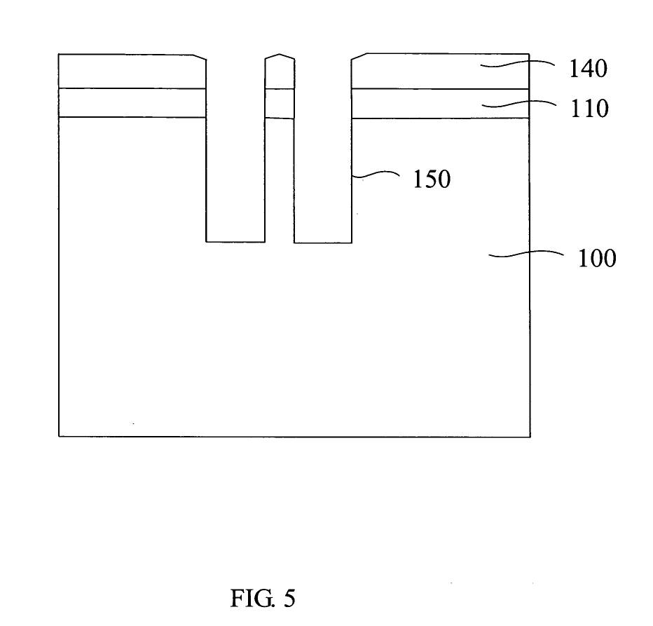

Still referring to FIG. 4, similar to conventional processes, a polymer layer 131 is formed on the sidewall of the trench 50 after the completion of the first etching step. However, it is advantageous to remove the polymer layer 131 to facilitate the formation of a protection layer required for the second etching step. Any conventional approaches suitable for removing the polymer layer can be adopted. For example, but not limited to, an isotropic wet etching process with the use of a mixture comprising a high temperature sulfuric acid, hydrogen peroxide, and ammonia can be utilized to clean the sidewall and remove the polymer 131 therefrom. The cleaning process also removes from the sidewall any residues or particles left by the first etching step. FIG. 5 shows the schematic view of the sidewall of the trench 150 after cleaning.

Moreover, it is noted that the value of the first predetermined depth is decided by a real depth where striation possibly occurs on the trench sidewall. The first predetermined depth is preferably neither too deep nor too shallow. If the first predetermined depth is too deep, a small area with striation may be generated on the corners of the sidewall due to over etching before the protection layer is formed thereon. On the contrary, if the first predetermined depth is not deep enough, i.e. the first etching step is stop too early, the protection layer formed on the sidewall is not thick enough to provide sufficient protection during the second etching step.

In general, the first predetermined depth ranges from 1.5 nanometers to 4 nanometers, preferably, from 2.5 nanometers to 3.5 nanometers. The depth (including the first predetermined depth and the second predetermined depth) refers to the length measured from the surface of the silicon substrate 100 to the bottom of the trench.

It is noted that the patterned composite layer 140 is also partially removed during the first etching step. Consequently, after the first etching step, only a portion of the sacrificial layer 120 of the patterned composite layer 140, which originally includes the sacrificial layer 120 and the mask layer 130, will be left on the pad layer 110. For instance, in the case that the sacrificial layer 120 is a composite layer comprising a BSG layer 121 and a USG layer 122, the mask layer 130, the USG layer 122, and a portion of the BSG layer 121 are removed simultaneously during the first etching step, leaving only a portion of the BSG layer 121.

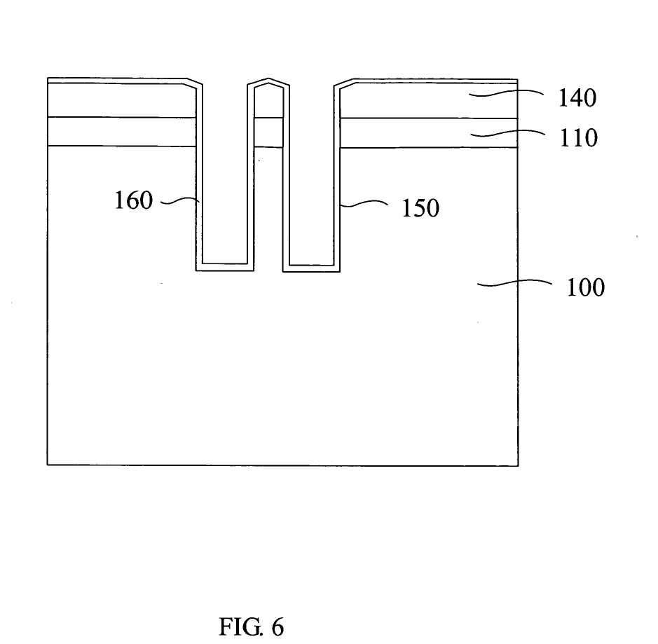

Next, referring to FIG. 6, an oxide film 160 is formed on the sidewall of the trench 150 to act as a protection layer for the following second etching step. In a preferred embodiment, the oxide film 160 is formed by a rapid thermal process (RTP), i.e., heating the silicon substrate 100 to a temperature ranging from 900° C. to 1100° C., preferably from 1000° C. to 1050° C. in the presence of oxygen, to form a silicon dioxide film over the sidewall of the trench. In general, a silicon dioxide film with a thickness ranging from 90 Å to 110 Å, preferably from 95 Å to 105 Å, can effectively protect the sidewall in the subsequent etching step.

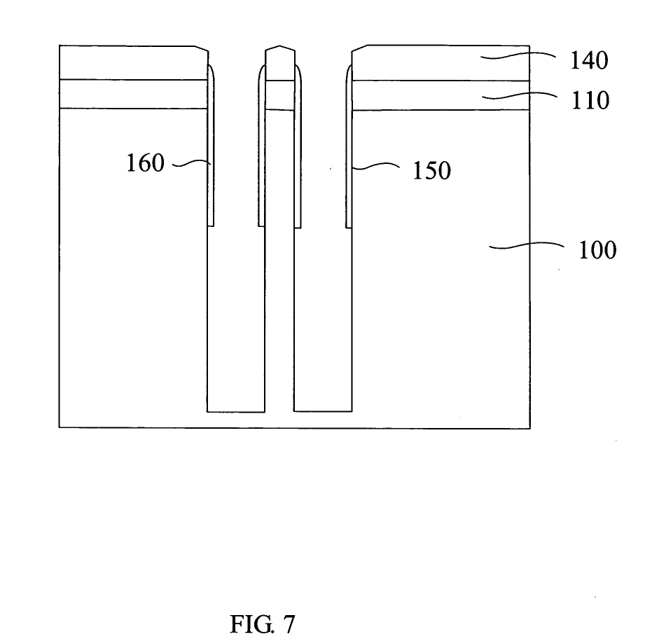

Last, the second etching step is performed. Referring to FIG. 7, the portion of silicon substrate 100 exposed outside the mask and under the trench 150 is partially removed by using the patterned composite layer 140 as a mask, until the depth of trench 150 reaches the second predetermined depth. For example, in the application of DRAM, the value of the second predetermined depth depends on the requirement for the storage node of the DRAM device. As to the current trench manufacturing processes, the second predetermined depth generally ranges from 7 nanometers to 9 nanometers, preferably from 7.5 nanometers to 8.5 nanometers.

The subject invention uses a two-step process to form a trench with a desired depth, which involves the formation of a protection layer on the sidewall of the trench by thermal oxidation before etching the trench to the desired depth. This process eliminates problems related to striation due to over etching and insufficient protection on the corners of trench, which are inherent in conventional processes. In other words, a deep trench capacitor with a regular contour in structure can be provided by the process of the subject invention so that the problems of shorts and leakages between neighboring capacitors can be solved under the current trends of the reduction in size of a DRAM device.

The above examples are only intended to illustrate the principle and efficacy of the subject invention, not to limit the subject invention. Any people skilled in this field may proceed with modifications and changes to the above examples without departing from the technical principle and spirit of the subject invention. Therefore, the scope of protection of the subject invention is covered in the following claims as appended.

What is claimed is:

1. A two-step process for manufacturing a deep trench in a substrate comprising:
removing a portion of the substrate to form a trench with a first predetermined depth;
cleaning the sidewall of the trench;
conducting a thermal oxidation to form an oxide film on the sidewall of the trench; and
removing a portion of the substrate under the trench to form a deep trench with a second predetermined depth.

2. The process of claim 1, wherein the step of removing a portion of the substrate to form a trench with a first predetermined depth comprises:
forming a patterned composite layer on the substrate; and
removing a portion of the substrate by using the patterned composite layer as a mask.

3. The process of claim 2, wherein the step of forming the patterned composite layer comprises:
forming a sacrificial layer on the substrate;
forming a mask layer on the sacrificial layer;
patterning the mask layer; and
patterning the sacrificial layer by using the mask layer as a mask.

4. The process of claim 3, wherein the sacrificial layer is a silicon oxide layer.

5. The process of claim 4, wherein the silicon oxide layer is a composite layer comprising a BSG layer and an USG layer.

6. The process of claim 3, wherein the mask is a polysilicon layer.

7. The process of claim 3, wherein a pad layer is formed on the substrate prior to the formation of the sacrificial layer.

8. The process of claim 7, wherein the pad layer is patterned along with the patterning of the sacrificial layer.

9. The process of claim 7, wherein the pad layer is a silicon nitride layer.

10. The process of claim 1, wherein a mixture of high temperature sulfuric acid, hydrogen peroxide, and ammonia is used for the step of cleaning the sidewall of the trench.

11. The process of claim 1, wherein the first predetermined depth ranges from 1.5 nanometers to 4 nanometers.

12. The process of claim 11, wherein the first predetermined depth ranges from 2.5 nanometers to 3.5 nanometers.

13. The process of claim 1, wherein the step of conducting a thermal oxidation is to heat the substrate to a temperature ranges from 900° C. to 1100° C. in the presence of oxygen.

14. The process of claim 13, wherein the temperature ranges from 1000° C. to 1050° C.

15. The process of claim 1, wherein the thickness of the oxide film ranges from 90 Å to 110 Å.

16. The process of claim 15, wherein the thickness of the oxide film ranges from 95 Å to 105 Å.

17. The process of claim 1, wherein the second predetermined depth ranges from 7 nanometers to 9 nanometers.

18. The process of claim 17, wherein the second predetermined depth ranges from 7.5 nanometers to 8.5 nanometers.

19. The process of claim 1, wherein the substrate is a silicon substrate.
